(19) United States
(12) Patent Application Publication
(10) Pub. No.: US 2022/0351996 A1
(43) Pub. Date: Nov. 3, 2022

(54) FRONT OPENING UNIFIED POD, WAFER TRANSFER SYSTEM AND WAFER TRANSFER METHOD

(71) Applicant: CHANGXIN MEMORY TECHNOLOGIES, INC., Hefei City (CN)

(72) Inventors: Yanbin LI, Hefei (CN); Su Yang, Hefei (CN); Xingfeng Hong, Hefei (CN); Yiqun Li, Hefei (CN)

(21) Appl. No.: 17/667,654

(22) Filed: Feb. 9, 2022

Related U.S. Application Data
(63) Continuation of application No. PCT/CN2021/114096, filed on Aug. 23, 2021.

(30) Foreign Application Priority Data
Apr. 29, 2021 (CN) 202110474775.2

(51) Int. Cl. H01L 21/67; H01L 21/677; H01L 21/673

(52) U.S. Cl. CPC H01L 21/67265; H01L 21/67781; H01L 21/67303; H01L 21/67282

(57) ABSTRACT

The application relates to the technical field of semiconductor manufacturing, and in particular relates to a front opening unified pod, a wafer transfer system and a wafer transfer method. The front opening unified pod includes a body, a wafer scanning device and a cover. The body is provided with an opening communicating with an interior of the body. The wafer scanning device includes a first wafer scanning device, is arranged on an inner wall of the body, and is configured to scan a storage condition of wafers in the body. The cover is fastened at the opening. The wafer scanning device is arranged on the inner wall of the body of the front opening unified pod, and the wafer scanning device scans and confirms the storage condition of the wafers in the front opening unified pod in real time.

### CROSS-REFERENCE TO RELATED APPLICATIONS

This application is a continuation application of International Patent Application No. PCT/CN2021/114096, filed on Aug. 23, 2021, which claims priority to Chinese Patent Application No. 202110474775.2, filed on Apr. 29, 2021 and entitled “FRONT OPENING UNIFIED POD, WAFER TRANSFER SYSTEM AND WAFER TRANSFER METHOD”. The contents of International Patent Application No. PCT/CN2021/114096 and Chinese Patent Application No. 202110474775.2 are hereby incorporated by reference in their entireties.

### TECHNICAL FIELD

The application relates to the technical field of semiconductor manufacturing, and in particular relates to a front opening unified pod, a wafer transfer system and a wafer transfer method.

### BACKGROUND

An advanced process for manufacturing integrated circuit generally includes hundreds of operations. Small errors in any operation will lead to the failure of a whole chip. Especially, with the continuous reduction of the critical size of a circuit, requirements for process control are stricter. In order to avoid misoperation, it is necessary to scan wafers in a front opening unified pod to confirm the position and the number of the wafers before the front opening unified pod is placed on a machine and before the front opening unified pod leaves the machine.

In the related art, a mechanical arm is adopted to scan the position and the number of the wafers, and each scanning takes about more than ten seconds. In this way, a lot of time is wasted and the production capacity is reduced in the whole manufacturing process.

### SUMMARY

The embodiments of the application provide a front opening unified pod, including a body, a wafer scanning device and a cover.

The body is provided with an opening communicating with an interior of the body.

The wafer scanning device includes a first wafer scanning device, is arranged on an inner wall of the body, and is configured to scan a storage condition of wafers in the body.

The cover is fastened at the opening.

The embodiments of the application also provide a wafer transfer system, including a front opening unified pod, a machine and a control system.

The front opening unified pod includes a body, a wafer scanning device and a cover. The body is provided with an opening communicating with an interior of the body. The wafer scanning device includes a first wafer scanning device, is arranged on an inner wall of the body, and is configured to scan a storage condition of wafers in the body. The cover is fastened at the opening.

The machine includes a bearing platform and a wafer transfer device. The front opening unified pod is located on the bearing platform, and the wafer transfer device is configured to transfer the wafers into the front opening unified pod.

The control system is connected with the first wafer scanning device and the machine. The control system is configured to drive the first wafer scanning device to move in the front opening unified pod to scan the interior of the body, obtain wafer information in the front opening unified pod according to a scanning result of the first wafer scanning device, and send the wafer information to the machine. The wafer information includes the number and the position of the wafers in the front opening unified pod.

The embodiments of the application also provide a wafer transfer method based on a wafer transfer system. The method includes the following operations.

An interior of a body of a front opening unified pod is scanned by a first wafer scanning device of the front opening unified pod of the wafer transfer system. Wafer information in the front opening unified pod is obtained according to a scanning result of the first wafer scanning device. The wafer information is sent to the machine. The wafer information includes the number and the position of the wafers in the front opening unified pod.

### BRIEF DESCRIPTION OF THE DRAWINGS

In order to describe the technical solutions in the embodiments of the application or the related art more clearly, the drawings required to be used in descriptions about the embodiments or the related art will be simply introduced below. It is apparent that the drawings described below are only some embodiments of the application. Other drawings may further be obtained by those of ordinary skilled in the art according to these drawings without creative work.

FIG. 1 is a schematic diagram of an internal structure of a front opening unified pod in an embodiment.

FIG. 2 is a top view of an internal structure of a front opening unified pod in an embodiment.

FIG. 3 is a schematic diagram of a wafer transfer system in another embodiment.

FIG. 4 is a schematic diagram of a wafer back with a serial number in an embodiment.

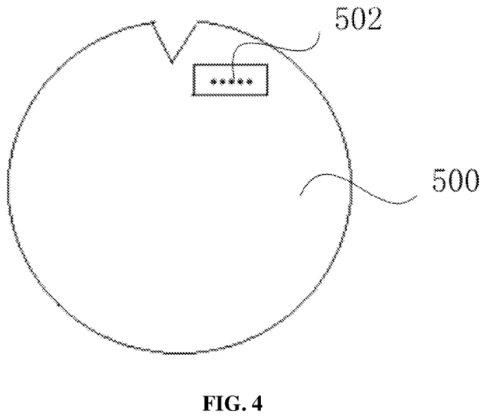

FIG. 5 is a schematic diagram of a wafer transfer system in a still another embodiment.

List of reference numerals: 100. front opening unified pod; 102. body; 104. first wafer scanning device; 1042. first sliding assembly; 1044. second sliding assembly; 1046. signal transmitter; 1048. signal receiver; 106. second wafer scanning device; 108. support assembly; 1082. support block; 200. machine; 300. control system; 400. wafer transfer device; 500. wafer; 502. serial number.

### DETAILED DESCRIPTION

The application is further described in combination with the drawings below.

In order to make the application convenient to understand, various embodiments defined by the claims of the application will be described more comprehensively below with reference to the related drawings. Preferred embodiments of the application are shown in the drawings, which contain various specific details to facilitate this understanding, but these details should be considered as exemplary only. However, the application may be implemented in various forms and is not limited to the embodiments described herein. Accordingly, those skilled in the art will recognize that the various embodiments described herein may be changed and improved without departing from the scope of the application defined by the appended claims. Moreover, for clarity and brevity, descriptions of well-known functions and configurations may be omitted.

It is apparent to those skilled in the art that, the following description of various embodiments of the application is provided for the purpose of interpretation only, and not for the purpose of limiting the application defined by the appended claims.

According to the description and the claims throughout the application document, the words “comprise” and “include” and variants of the words such as “consist of” and “comprise” mean “include but not limited to”, and are not intended to (and will not) exclude other parts, wholes or steps. Features, wholes or characteristics described in combination with specific aspects, embodiments or examples of the application will be understood to be applicable to any other aspect, embodiment or example described herein unless incompatible with it.

It should be understood that the singular forms “one”, “a” and “the” include references to the plural, unless the context expressly provides otherwise. The expressions “include” and/or “may include” used in this application are intended to indicate the existence of corresponding functions, operations or elements, rather than to limit the existence of one or more functions, operations and/or elements. Moreover, in the application, the terms “include” and/or “have” are intended to indicate the existence of characteristics, numbers, operations, elements and components, or combinations thereof, as disclosed in the application document. Therefore, the terms “include” and/or “have” should be understood to mean that there are additional possibilities for one or more other characteristics, numbers, operations, elements and components, or combinations thereof.

In the application, the expression “or” contains any or all combinations of words listed together. For example, “A or B” may contain A or B, or both A and B.

It should be understood that, when an element is referred to as “fixed to” another element, it may be directly on another element or there may be an intermediate element. When an element is considered to be “connected” or “coupled” to another element, it may be directly coupled to another element, or there may be intermediate elements at the same time.

The “up”, “down”, “left” and “right” mentioned in the application are only used to represent the relative position relationship. When the absolute position of the described object changes, the relative position relationship may also change accordingly.

Unless otherwise defined, all technical terms and scientific terms used herein have the same meanings as commonly understood by those skilled in the art that the application belongs to. It should also be understood that, terms (such as those defined in common dictionaries) should be interpreted as having a meaning consistent with the relevant field and the context of the specification, and should not be interpreted in an idealized or overly formal sense, unless explicitly defined herein. The term “and/or” as used herein includes any and all combinations of one or more related listed items.

It is understood that, the terms “first”, “second” and the like used in the application may be used to describe various elements herein, but these elements are not limited by these terms. These terms are only used to distinguish the first element from another element.

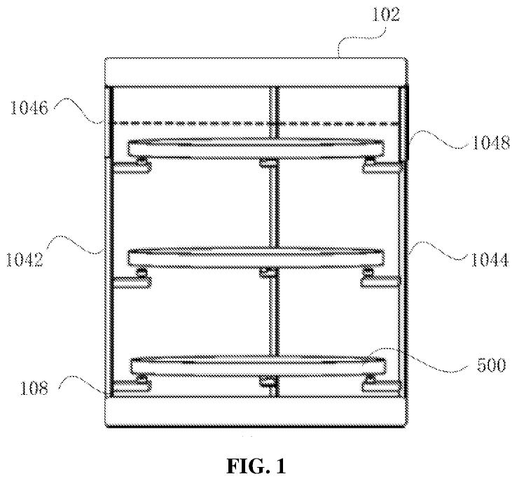

As shown in FIG. 1 to FIG. 3, in an embodiment of the application, a front opening unified pod (FOUP) 100 is provided, which includes a body 102, a wafer scanning device and a cover. The body 102 is provided with an opening communicating with an interior of the body 102. The wafer scanning device includes a first wafer scanning device 104, is arranged on an inner wall of the body 102, and is configured to scan the storage condition of wafers 500 in the body 102. The cover is fastened at the opening.

Specifically, the body 102 is provided with the opening communicating with the interior of the body 102, so that the wafer 500 may enter the interior of the body 102 through the opening and leave the body of the front opening unified pod 100 through the opening. The wafer scanning device is arranged on the inner wall of the body of the front opening unified pod 100, and the wafer scanning device includes the first wafer scanning device 104. When the front opening unified pod 100 is placed on a machine 200 and before the front opening unified pod 100 leaves the machine 200, the wafer scanning device scans the wafer 500 in the front opening unified pod 100 to confirm the storage condition of the wafers 500 in the front opening unified pod 100. The cover is arranged at the opening of the body of the front opening unified pod 100. The cover may be opened or closed when the wafer 500 enters and leaves the interior of the body 102. The cover isolates the internal space of the body of the front opening unified pod 100 from the external environment to prevent the wafer 500 in the front opening unified pod from being contaminated.

Specifically, the wafer scanning device is arranged on the inner wall of the body 102 of the front opening unified pod 100, and the wafer scanning device scans and confirms the storage condition of the wafers 500 in the front opening unified pod 100 in real time. The condition that a mechanical arm of the machine 200 is required to scan the wafers 500 in the front opening unified pod 100 to confirm the storage condition of the wafers 500 in the front opening unified pod 100 when the front opening unified pod 100 is placed on the machine 200 every time may be replaced. Therefore, a lot of time may be saved and thus the production capacity may be improved. Moreover, there is no need to buy a relatively complete set of mechanical arm equipment, which saves the equipment cost. There is no need to set mechanical arm equipment, which saves the space on the machine 200.

In an embodiment, the first wafer scanning device 104 may include a first sliding assembly 1042, a signal transmitter 1046, a second sliding assembly 1044, a signal receiver 1048 and a driving device. The first sliding assembly 1042 is located on the inner wall of the body 102, and the first sliding assembly 1042 extends along a height direction of the body 102. The signal transmitter 1046 is located on the first sliding assembly 1042 and is slidable along the first sliding assembly 1042. The signal transmitter 1046 is configured to transmit a detection signal. The second sliding assembly 1044 is located on the inner wall of the body 102 and is arranged opposite to the first sliding assembly 1042. The second sliding assembly 1044 extends along the height direction of the body 102. The signal receiver 1048 is located on the second sliding assembly 1044 and is slidable along the second sliding assembly 1044. The signal receiver 1048 is configured to receive the detection signal. The driving device is connected with the signal transmitter 1046 and the signal receiver 1048, and is configured to drive the signal transmitter 1046 and the signal receiver 1048 to slide synchronously.

Specifically, the first sliding assembly 1042 extends along the height direction of the front opening unified pod 100 and is arranged on the inner wall of the front opening unified pod 100. The signal transmitter 1046 is arranged on the first sliding assembly 1042 and is slidable along the first sliding assembly 1042. The second sliding assembly 1044 is also arranged on the inner wall of the front opening unified pod 100 and extends along the height direction of the front opening unified pod 100, and is arranged opposite to the first sliding assembly 1042. The signal receiver 1048 is arranged on the second sliding assembly 1044 and is slidable along the second sliding assembly 1044. The driving device is connected with the signal transmitter 1046 and the signal receiver 1048. The driving device drives the signal transmitter 1046 and the signal receiver 1048 to move synchronously on the first sliding assembly 1042 and the second sliding assembly 1044 respectively.

Specifically, the signal transmitter 1046 is configured to transmit the detection signal, and the signal receiver 1048 is configured to receive the detection signal transmitted by the signal transmitter 1046. The detection signal may be an infrared signal or other detection signals, which are not limited here. The driving device drives the signal transmitter 1046 and the signal receiver 1048 to move synchronously on the first sliding assembly 1042 and the second sliding assembly 1044 respectively. The signal transmitter 1046 and the signal receiver 1048 move synchronously to ensure that the signal receiver 1048 movable on the second sliding assembly 1044 may receive the detection signal transmitted by the first sliding assembly 1042 during synchronous movement.

When the driving device drives the signal transmitter 1046 and the signal receiver 1048 to move synchronously, the detection signal transmitted by the signal transmitter 1046 is shielded by the wafers 500 in the front opening unified pod 100 to form a detection signal with variable intensity. The signal receiver 1048 records the storage condition of the wafers 500 in the front opening unified pod 100 according to the received detection signal with variable intensity. As designed in this way, the condition that a mechanical arm of the machine 200 is required to scan the wafers 500 in the front opening unified pod 100 to confirm the storage condition of the wafers 500 in the front opening unified pod 100 when the front opening unified pod 100 is placed on the machine 200 every time may be replaced. A lot of scanning time of the mechanical arm may be saved and thus the production capacity may be improved.

In an embodiment, each of the first sliding assembly 1042 and the second sliding assembly 1044 may include a sliding guide rail or a sliding frame.

Specifically, the first sliding assembly 1042 and the second sliding assembly 1044 are sliding guide rails, which extend along the height direction of the front opening unified pod 100 and are arranged on the inner wall of the front opening unified pod 100 opposite to each other, and the signal transmitter 1046 and the signal receiver 1048 are arranged on the sliding guide rails and are slidable on the sliding guide rails respectively. The signal transmitter 1046 and the signal receiver 1048 are arranged opposite to each other to ensure that the detection signal transmitted by the signal transmitter 1046 is received by the signal receiver 1048 after passing through the wafers 500 in the front opening unified pod 100. The sliding guide rails ensure that the signal transmitter 1046 and the signal receiver 1048 move along the height direction of the front opening unified pod 100 under the driving of the driving device. The sliding guide rails may also adopt other sliding components, which are not limited here.

Specifically, the first sliding assembly 1042 and the second sliding assembly 1044 are sliding frames, which extend along the height direction of the front opening unified pod 100 and are arranged on the inner wall of the front opening unified pod 100 opposite to each other, and the signal transmitter 1046 and the signal receiver 1048 are arranged on the sliding frames and are slidable on the sliding frames respectively. The signal transmitter 1046 and the signal receiver 1048 are arranged opposite to each other to ensure that the detection signal transmitted by the signal transmitter 1046 is received by the signal receiver 1048 after passing through the wafers 500 in the front opening unified pod 100. The sliding frames ensure that the signal transmitter 1046 and the signal receiver 1048 move along the height direction of the front opening unified pod 100 under the driving of the driving device. The sliding frames may also adopt other sliding components, which are not limited here.

In an embodiment, the signal transmitter 1046 may include an infrared signal transmitter 1046, and the signal receiver 1048 may include an infrared signal receiver 1048.

Specifically, the signal transmitter 1046 is an infrared signal transmitter 1046, and the signal receiver 1048 is an infrared signal receiver 1048. When the infrared signal transmitter 1046 and the infrared signal receiver 1048 are driven by the driving device to move synchronously on the first sliding assembly 1042 and the second sliding assembly 1044 respectively, an infrared detection signal transmitted by the infrared signal transmitter 1046 is shielded by the wafers 500 in the front opening unified pod 100 to form an infrared detection signal with variable intensity during transmission of the infrared detection signal in the front opening unified pod 100, and the infrared signal receiver 1048 records the storage condition of the wafers 500 in the front opening unified pod 100 according to the received infrared detection signal with variable intensity which is formed by the shielding of the wafers 500. Thus, the infrared signal transmitter 1046 and the infrared signal receiver 1048 scan the wafers 500 in the front opening unified pod 100 to confirm the storage condition of the wafers 500 in the front opening unified pod 100.

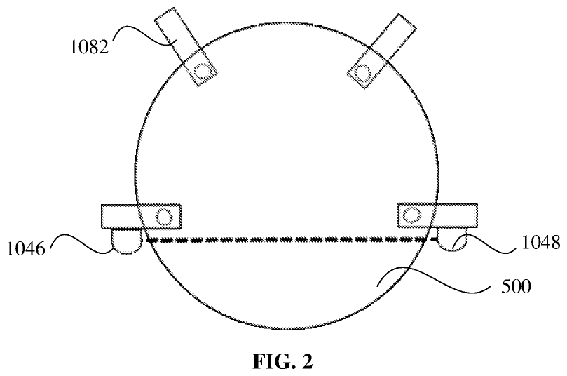

Please referring to FIG. 2, in an embodiment, both the first sliding assembly 1042 and the second sliding assembly 1044 extend from the top of the body 102 to the bottom of the body 102.

Specifically, the first sliding assembly 1042 and the second sliding assembly 1044 extend along the height direction of the front opening unified pod 100, and are arranged on the inner wall of the front opening unified pod 100. Both the first sliding assembly 1042 and the second sliding assembly 1044 extend from the top of the body 102 to the bottom of the body 102. As designed in this way, the signal transmitter 1046 arranged on the first sliding assembly 1042 and the signal receiver 1048 arranged on the second sliding assembly 1044 may be slidable from the top of the body 102 to the bottom of the body 102 to ensure that the wafer scanning device may scan all the wafers 500 placed in the front opening unified pod 100. The storage condition of the wafers 500 obtained through the scanning is more accurate, and the production efficiency is ensured.

In an embodiment, the front opening unified pod may also include a plurality of groups of support assemblies 108 configured to support the wafers 500 and fixed on an inner wall of an accommodating space. The plurality of groups of support assemblies 108 are arranged at intervals along the height direction of the body 102 and are parallel to each other. Each group of support assemblies 108 may include a plurality of support blocks 1082 arranged at intervals along the circumferential direction of the accommodating space.

Specifically, the front opening unified pod 100 may also include a plurality of groups of support assemblies 108 configured to support the wafers 500. The plurality of groups of support assemblies 108 are arranged at intervals along the height direction of the body 102, the plurality of groups of support assemblies 108 are parallel to each other, and the plurality of support blocks 1082 of each group of the plurality of groups of support assemblies 108 are arranged at intervals along the circumferential direction of the accommodating space. The first sliding assembly 1042 and the second sliding assembly 1044 are arranged on the inner wall of the front opening unified pod 100 opposite to each other, and are adjacent to the support assemblies 108 arranged opposite to each other in each group respectively. The support assemblies 108 in each group of support assemblies 108 adjacent to the first sliding assembly 1042 and the second sliding assembly 1044 are arranged in a direction parallel to the detection signal.

As designed in this way, the wafers 500 placed on the plurality of groups of support assemblies 108 may be arranged in the front opening unified pod 100 at intervals along the height direction of the body 102 and are parallel to each other, so that during the synchronous movement of the signal transmitter 1046 and the signal receiver 1048 along the height direction of the front opening unified pod 100, the detection signal transmitted by the signal transmitter 1046 is shielded by the wafers 500 to generate a detection signal with variable intensity, and then the storage condition of the wafers 500 is recorded. In each group of support assemblies 108, the support assemblies 108 adjacent to the first sliding assembly 1042 and the second sliding assembly 1044 are arranged in a direction parallel to the detection signal to prevent inaccurate storage condition of the wafers 500 from being obtained due to the shielding of the detection signal by the support assemblies 108.

In an embodiment, the wafer scanning device may also include a second wafer scanning device 106. The second wafer scanning device 106 is arranged at the bottom of the body 102 and is located at the opening. The second wafer scanning device 106 is configured to scan and record a serial number 502 of the wafer 500 when the wafer 500 is transferred into the body 102.

Specifically, the second wafer scanning device 106 is arranged at the bottom of the opening of the body 102. When the wafer 500 is transferred to the body 102, the serial number 502 of the wafer 500 is scanned and recorded. This ensures that the transferred wafer 500 is consistent with the material ledger, avoids erroneous transfer, reduces the personnel workload, saves the production cost, and further improves the transfer efficiency.

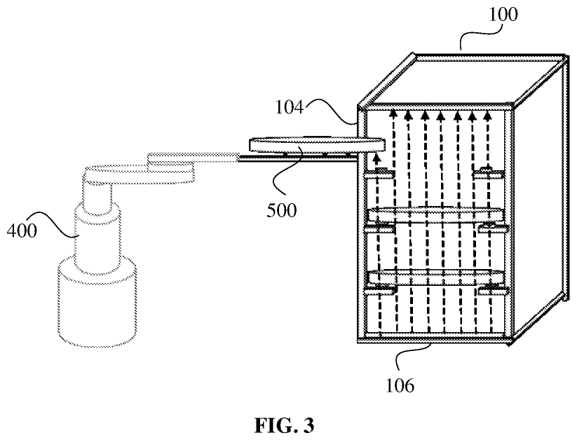

Please referring to FIG. 3, the application further provides a wafer transfer system, which includes the front opening unified pod 100 according to any one of the above embodiments, a machine 200 and a control system 300. The machine 200 includes a bearing platform and a wafer transfer device 400, the front opening unified pod 100 is located on the bearing platform, and the wafer transfer device 400 is configured to transfer a wafer 500 into the front opening unified pod 100. The control system 300 is connected with the first wafer scanning device 104 and the machine 200, and is configured to drive the first wafer scanning device 104 to move in the front opening unified pod 100 to scan the interior of the body 102, obtain wafer information in the front opening unified pod 100 according to the scanning result of the first wafer scanning device 104, and send the wafer information to the machine 200. The wafer information includes the number and the position of the wafers 500 in the front opening unified pod 100.

Specifically, the front opening unified pod 100 is located on the bearing platform, and the control system 300 is connected with the first wafer scanning device 104 and the machine 200. When the control system 300 drives the signal transmitter 1046 and the signal receiver 1048 to move synchronously, the detection signal transmitted by the signal transmitter 1046 is shielded by the wafers 500 in the front opening unified pod 100 to form a detection signal with variable intensity. The interior of the body 102 is scanned according to the detection signal with variable intensity received by the signal receiver 1048. The wafer information in the front opening unified pod 100 is obtained according to the scanning result of the first wafer scanning device 104. The wafer information includes the number and the position of the wafers 500 in the front opening unified pod 100, and the wafer information is sent to the machine 200.

The first wafer scanning device scans the front opening unified pod 100 and records the storage condition of the wafers 500 in the front opening unified pod 100. As designed in this way, the condition that a mechanical arm of the machine 200 is required to scan the wafers 500 in the front opening unified pod 100 to confirm the storage condition of the wafers 500 in the front opening unified pod 100 when the front opening unified pod 100 is placed on the machine 200 every time may be replaced. A lot of scanning time of the mechanical arm may be saved and thus the production capacity may be improved.

In an embodiment, a communication device may also be included, which is connected with the control system 300 and is configured to send the scanning result to the control system 300. The communication device may be a wired communication device or a wireless communication device, which is not limited here. The communication device sends the scanning result, namely the storage condition of the wafers 500 in the front opening unified pod 100, to the control system 300.

In an embodiment, the wafer transfer device 400 may include a mechanical arm. The wafer transfer device 400 transfers the wafer 500 into the front opening unified pod 100 or transfers the wafer 500 out of the front opening unified pod 100.

Please referring to FIG. 3, in an embodiment, the wafer scanning device may also include a second wafer scanning device 106 arranged at the bottom of the body 102 and located at the opening. The second wafer scanning device 106 is configured to scan and record the serial number 502 of the wafer 500 when the wafer is transferred into the body 102. The control system 300 is also connected with the second wafer scanning device. The control system 300 is also configured to compare the serial number 502 scanned and recorded by the scanning device of the serial number 502 with the target serial number 502, and send alarm control information to the machine 200 when the comparison result indicates that the scanned and recorded serial number 502 is inconsistent with the target serial number 502. After receiving the alarm control information, the machine 200 gives an alarm and stops the transfer of the wafer 500.

Specifically, the second wafer scanning device 106 is arranged at the bottom of the opening of the body 102. The control system 300 controls the second wafer scanning device 106 to scan and record the serial number 502 of the wafer 500 when the wafer 500 is transferred into the body 102. The control system 300 compares the scanned serial number 502 with the target serial number 502, and sends alarm control information to the machine 200 when the comparison result indicates that the scanned serial number 502 is inconsistent with the target serial number 502. After receiving the alarm control information, the machine 200 gives an alarm and stops the transfer of the wafer 500. The scanned serial number 502 is compared with the target serial number 502, which ensures that the transferred wafer 500 is consistent with the material ledger, avoids erroneous transfer, reduces the personnel workload, and further improves the transfer efficiency.

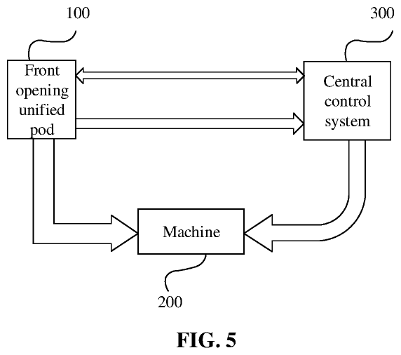

Please referring to FIG. 5, in an embodiment, the control system 300 may include a central control system for the machine 200.

Specifically, when the central control system drives the signal transmitter 1046 and the signal receiver 1048 to move synchronously, the detection signal transmitted by the signal transmitter 1046 is shielded by the wafers 500 in the front opening unified pod 100 to form a detection signal with variable intensity. The central control system generates wafer information in the front opening unified pod 100 according to the detection signal with variable intensity received by the signal receiver 1048, and sends the wafer information to the machine 200, and the wafer information may include the number and the position of the wafers 500 in the front opening unified pod 100.

Specifically, the central control system controls the second wafer scanning device 106 to scan and record the serial number 502 of the wafer 500 when the wafer 500 is transferred into the body 102. The central control system compares the scanned serial number 502 with the target serial number 502, and sends alarm control information to the machine 200 when the comparison result indicates that the scanned serial number 502 is inconsistent with the target serial number 502. After receiving the alarm control information, the machine 200 gives an alarm and stops the transfer of the wafer 500. The scanned serial number 502 is compared with the target serial number 502, which ensures that the transferred wafer 500 is consistent with the material ledger, avoids erroneous transfer, reduces the personnel workload, and further improves the transfer efficiency.

The application further provides a wafer transfer method based on the wafer transfer system according to any one of the above embodiments. The method includes the following operations. The interior of the body 102 is scanned by the first wafer scanning device 104. The wafer information in the front opening unified pod 100 is obtained according to the scanning result of the wafer scanning device, and the wafer information is sent to the machine 200. The wafer information includes the number and the position of the wafers 500 in the front opening unified pod 100.

Specifically, the control system 300 controls the first wafer scanning device 104 to scan the interior of the body 102, generates wafer information in the front opening unified pod 100, and sends the wafer information to the machine 200. The wafer information is the number and the position of the wafers in the front opening unified pod 100. Therefore, the condition that a mechanical arm of the machine 200 is required to scan the wafers 500 in the front opening unified pod 100 to confirm the storage condition of the wafers 500 in the front opening unified pod 100 when the front opening unified pod 100 is placed on the machine 200 every time may be avoided, which may save a lot of scanning time of the mechanical arm and in turn improve the production capacity.

In an embodiment, the wafer scanning device may also include a second wafer scanning device 106 arranged at the bottom of the body 102 and located at the opening. The wafer transfer method may also include the following operations. The serial number 502 of the wafer 500 is scanned and recorded by the second wafer scanning device 106 when the wafer 500 is transferred into the body 102. The serial number 502 scanned and recorded by the scanning device of the serial number 502 is compared with the target serial number 502, and alarm control information is sent to the machine 200 when the comparison result indicates that the scanned and recorded serial number 502 is inconsistent with the target serial number 502.

Specifically, the second wafer scanning device 106 is configured to scan and record the serial number 502 of the wafer 500. The scanned serial number 502 is compared with the target serial number 502, and alarm control information is sent to the machine 200 when the comparison result indicates that the scanned serial number 502 is inconsistent with the target serial number 502. The scanned serial number 502 is compared with the target serial number 502, which ensures that the transferred wafer 500 is consistent with the material ledger, avoids erroneous transfer, reduces the personnel workload, and further improves the transfer efficiency.

In an embodiment, the wafer transfer method may also include the following operation. The machine 200 gives an alarm and stops the transfer of the wafer 500 after receiving the alarm control information.

Specifically, the machine 200 gives an alarm and stops the transfer of the wafer 500 after receiving the alarm control information, so as to ensure that the transferred wafer 500 is consistent with the material ledger and to avoid erroneous transfer.

It should be understood that, unless expressly stated in the description, there are no strict sequence restrictions on the execution of these operations, and these operations may be executed in other order. Moreover, at least part of operations may include a plurality of operations or a plurality of stages, these operations or stages are not executed necessarily at the same time, and may be executed at different times, and these operations or stages are not sequentially executed necessarily, and may be executed in turn or alternatively with other operations or at least part of sub- operations or stages in other operations.

Those of ordinary skill in the art will appreciate that implementing all or part of the processes in the methods described above may be accomplished by instructing associated hardware by a computer program, which may be stored in a non-volatile computer-readable storage medium, which, when executed, processes may be included as embodiments of the methods described above. Any reference to a memory, storage, a database, or other media used in the embodiments provided herein may include nonvolatile and/or volatile memories. A nonvolatile memory may include a Read-Only Memory (ROM), a Programmable ROM (PROM), an Electrically Programmable ROM (EPROM), an Electrically Erasable Programmable ROM (EEPROM), or a flash memory. A volatile memory may include a Random Access Memory (RAM) or an external cache memory. As not a limitation but an illustration, the RAM is available in many forms, such as a Static RAM (SRAM), a Dynamic RAM (DRAM), a Synchronous DRAM (SDRAM), a Double Data Rate SDRAM (DDRSDRAM), an Enhanced SDRAM (ESDRAM), a Synchronous Chain Channel (Synchlink) DRAM (SLDRAM), a Rambus Direct RAM (RDRAM), a Direct Memory Bus Dynamic RAM (DRDRAM), and a Memory Bus Dynamic RAM (RDRAM), among others.

Each technical feature of the above mentioned embodiments may be combined freely. For simplicity of description, not all possible combinations of each technical solution in the above mentioned embodiments are described. However, any combination of these technical features shall fall within the scope recorded in the specification without conflicting.

The above mentioned embodiments only express some implementation modes of the application and are specifically described in detail and not thus understood as limits to the patent scope of the application. It is to be pointed out that those of ordinary skill in the art may further make a plurality of transformations and improvements without departing from the concept of the application and all of these fall within the scope of protection of the application. Therefore, the scope of patent protection of the application should be subject to the appended claims.

1. A front opening unified pod, comprising:
a body, wherein the body is provided with an opening communicating with an interior of the body;
a wafer scanning device, wherein the wafer scanning device comprises a first wafer scanning device, is arranged on an inner wall of the body, and is configured to scan a storage condition of wafers in the body; and
a cover, wherein the cover is fastened at the opening.

2. The front opening unified pod according to claim 1, wherein the first wafer scanning device comprises:
a first sliding assembly, wherein the first sliding assembly is located on the inner wall of the body and extends along a height direction of the body;
a signal transmitter, wherein the signal transmitter is located on the first sliding assembly, is slidable along the first sliding assembly, and is configured to transmit a detection signal;
a second sliding assembly, wherein the second sliding assembly is located on the inner wall of the body, is arranged opposite to the first sliding assembly, and extends along the height direction of the body;
a signal receiver, wherein the signal receiver is located on the second sliding assembly, is slidable along the second sliding assembly, and is configured to receive the detection signal; and
a driving device, wherein the driving device is connected with the signal transmitter and the signal receiver, and is configured to drive the signal transmitter and the signal receiver to slide synchronously.

3. The front opening unified pod according to claim 2, wherein each of the first sliding assembly and the second sliding assembly comprises a sliding guide rail or a sliding frame.

4. The front opening unified pod according to claim 2, wherein the signal transmitter comprises an infrared signal transmitter, and the signal receiver comprises an infrared signal receiver.

5. The front opening unified pod according to claim 2, wherein each of the first sliding assembly and the second sliding assembly extends from a top of the body to a bottom of the body.

6. The front opening unified pod according to claim 1, further comprising a plurality of groups of support assemblies configured to support the wafers, wherein the plurality of groups of support assemblies are fixed on an inner wall of an accommodating space, the plurality of groups of support assemblies are arranged at intervals along a height direction of the body and are parallel to each other, and the plurality of groups of support assemblies comprises a plurality of support blocks arranged at intervals along a circumferential direction of the accommodating space.

7. The front opening unified pod according to claim 1, wherein the wafer scanning device further comprises:
a second wafer scanning device, wherein the second wafer scanning device is arranged at a bottom of the body and located at the opening, and the second wafer scanning device is configured to scan and record a serial number of each wafer when the wafer is transferred into the body.

8. A wafer transfer system, comprising:
a front opening unified pod, comprising:
a body, wherein the body is provided with an opening communicating with an interior of the body;
a wafer scanning device, wherein the wafer scanning device comprises a first wafer scanning device, is arranged on an inner wall of the body, and is configured to scan a storage condition of wafers in the body; and
a cover, wherein the cover is fastened at the opening;
a machine comprising a bearing platform and a wafer transfer device, wherein the front opening unified pod is located on the bearing platform, and the wafer transfer device is configured to transfer the wafers into the front opening unified pod; and
a control system connected with the first wafer scanning device and the machine, wherein the control system is configured to drive the first wafer scanning device to move in the front opening unified pod to scan the interior of the body, obtain wafer information in the front opening unified pod according to a scanning result of the first wafer scanning device, and send the wafer information to the machine, wherein the wafer information comprises a number and a position of the wafers in the front opening unified pod.

9. The wafer transfer system according to claim 8, further comprising a communication device, wherein the communication device is connected with the control system and is configured to send the scanning result to the control system.

10. The wafer transfer system according to claim 8, wherein the wafer transfer device comprises a mechanical arm.

11. The wafer transfer system according to claim 8, wherein the wafer scanning device further comprises a second wafer scanning device arranged at a bottom of the body and located at the opening, the second wafer scanning device is configured to scan and record a serial number of each wafer when the wafer is transferred into the body,
the control system is connected with the second wafer scanning device, the control system is configured to compare the serial number scanned and recorded by the second wafer scanning device of the serial number with a target serial number, and send alarm control information to the machine when a comparison result indicates that the scanned and recorded serial number is inconsistent with the target serial number, wherein the machine gives an alarm and stops the transfer of the wafers after receiving the alarm control information.

12. The wafer transfer system according to claim 8, wherein the control system comprises a central control system for the machine.

13. A wafer transfer method based on a wafer transfer system, comprising:
scanning, by a first wafer scanning device of a front opening unified pod of the wafer transfer system, an interior of a body of the front opening unified pod; obtaining wafer information in the front opening unified pod according to a scanning result of the first wafer scanning device; and sending the wafer information to a machine, wherein the wafer information comprises a number and a position of wafers in the front opening unified pod.

14. The wafer transfer method according to claim 13, wherein a second wafer scanning device is arranged at a bottom of the body and located at an opening of the body, wherein the wafer transfer method further comprises:
scanning and recording, by using a second wafer scanning device of the front opening unified pod, a serial number of each wafer when the wafer is transferred into the body; and
comparing the serial number scanned and recorded by the second wafer scanning device of the serial number with a target serial number, and sending alarm control information to the machine when a comparison result indicates that the scanned and recorded serial number is inconsistent with the target serial number.

15. The wafer transfer method according to claim 14, further comprising:
giving an alarm and stopping transfer of the wafers by the machine after the alarm control information is received by the machine.
